(19) United States
(12) Patent Application Publication
(10) Pub. No.: US 2022/0231225 A1
(43) Pub. Date: Jul. 21, 2022

(54) MEMORY SELECTOR

(71) Applicant: Commissariat à I'Énergie Atomique et aux Énergies Alternatives, Paris (FR)

(72) Inventors: Anthonin Verdy, Grenoble (FR); Gilbert Sassine, Grenoble (FR); Gabriel Molas, Grenoble (FR); Gabriele Navarro, Grenoble Cedex 9 (FR)

(73) Assignee: Commissariat à I'Énergie Atomique et aux Énergies Alternatives, Paris (FR)

(21) Appl. No.: 17/609,862

(22) PCT Filed: May 4, 2020
(86) PCT No.: PCT/FR2020/050741

§ 371 Date: Nov. 9, 2021

(30) Foreign Application Priority Data
May 10, 2019 (FR) 1904900

(51) Int. Cl. H01L 45/00; H01L 27/24

(52) U.S. Cl. CPC H01L 45/144; H01L 27/2427; H01L 27/2481; H01L 45/143; H01L 45/1625

(57) ABSTRACT

A selector for a memory cell, intended to change from a resistive state to a conductive state so as to respectively prohibit or authorize access to the memory cell, characterized in that it is made of an alloy consisting of germanium, selenium, arsenic and tellurium.

The present patent application claims the priority of the French patent application FR19/04900 that shall be considered as forming part of the present disclosure.

### TECHNICAL FIELD

The present disclosure relates generally to electronic devices and, more particularly, to resistive memories and their selectors. More particularly, the present disclosure applies to a composition of a given selector.

### BACKGROUND ART

Resistive random access memories integrated in “1T1R” type arrays are known. These arrays consist of structures comprising one transistor and one resistive cell. In such a structure, the transistor acts as a selector. This selector makes it possible to access the resistive memory cell, for read- or write- or erase- or programming operations (programming=write and erase) in a given memory cell, while limiting undesirable leakage currents in the rest of the memory array.

The selectors currently used in memory arrays have large dimensions as compared to those of the resistive cell. As a result, this impairs the density of memory arrays.

### SUMMARY OF INVENTION

There is a need to optimize current selector elements.

One embodiment addresses all or some of the drawbacks of known selector elements.

One embodiment provides a selector for a memory cell, intended to change from a resistive state to a conductive state so as to prohibit or authorize access to the memory cell, respectively, characterized in that it is made of a GS-AT alloy consisting of germanium, selenium, arsenic and tellurium.

According to one embodiment, said GS-AT alloy is Ge₃Se₇As₂Te₃.

According to one embodiment, said GS-AT alloy has an arsenic and tellurium AT compound content of between 20% and 80%.

According to one embodiment, said GS-AT alloy has an arsenic and tellurium compound content AT of 40%.

According to one embodiment, said GS-AT alloy is obtained by physical vapor deposition.

According to one embodiment, said selector is an ovonic threshold switch.

One embodiment provides a memory point comprising:
a resistive memory element; and
a selector switch, as described.

According to one embodiment, the proportions of arsenic, tellurium, germanium and selenium are such that a threshold voltage of said selector is greater than or equal to a programming voltage of said resistive memory element.

According to one embodiment, the arsenic and tellurium content of the compound AT and the germanium and selenium content of the compound GS are such that a threshold voltage of said selector is greater than or equal to a programming voltage of said resistive memory element.

According to one embodiment, the arsenic and tellurium content of the compound AT and the germanium and selenium content of the compound GS are such that a threshold voltage of said selector is less than or equal to a state switching current of said resistive memory element.

One embodiment provides a memory having a plurality of memory points as described.

According to one embodiment, the memory is a resistive oxide memory or a conductive link random access memory.

According to one embodiment, each memory point comprises, in series:
said selector;
said resistive memory element; and
an electrically conductive layer interposed between said selector and said resistive memory element.

According to one embodiment, the memory points are organized as an array.

According to one embodiment, each memory point is interposed between a first conductor and a second conductor.

One embodiment provides for such a memory comprising a three-dimensional stack of memory points, as described, separated by conductors.

One embodiment provides a method for manufacturing a memory comprising the following steps:
manufacturing at least one resistive memory element; and
in connection with said resistive memory element, manufacturing at least one selector made of an alloy consisting of germanium, selenium, arsenic and tellurium.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 is a simplified perspective view of one embodiment of a memory;

FIG. 2 shows schematically one embodiment of a memory point array;

FIG. 3 shows a current/voltage characteristic of one embodiment of a memory point;

FIG. 4 shows a variation curve of characteristic quantities of one embodiment of a selector element;

FIG. 5 shows another variation curve of characteristic quantities of one embodiment of a selector element; and

FIG. 6 shows still other variation curves of characteristic quantities of one embodiment of a selector element, in views A and B.

### DESCRIPTION OF EMBODIMENTS

Like features have been designated by like references in the various Figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the memory points may include elements not described, such as electrical connections.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the Figures, as orientated during normal use.

Unless specified otherwise, the expressions “around”, “approximately”, “substantially” and “in the order of” signify within 10%, and preferably within 5%.

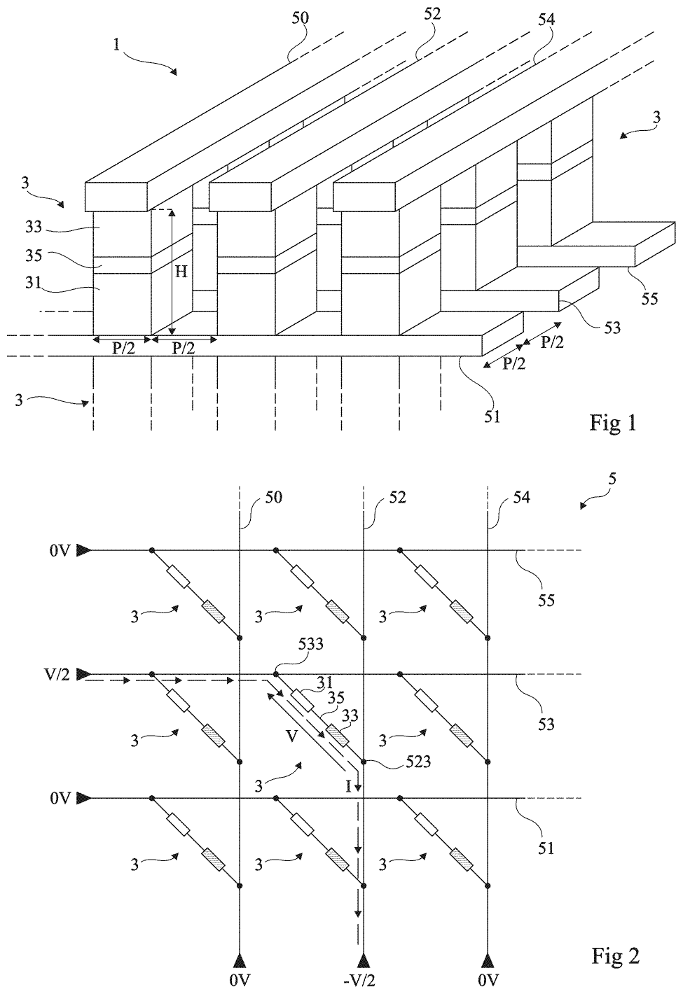

FIG. 1 is a simplified perspective view of one embodiment of a memory 1.

According to this embodiment, the memory 1 comprises memory points or cells 3 that make it possible to store all or part of a data item. The memory 1 also has electrical conductors 50, 51, 52, 53, 54 and 55. These conductors 50, 51, 52, 53, 54 and 55 are made of an electrically conductive metallic material such as copper.

The conductors 50, 51, 52, 53, 54 and 55 in FIG. 1 are arranged in such a way that they form an array, when viewed from above, in which each intersection or crossing corresponds to a memory point location. Of the conductors 50, 51, 52, 53, 54 and 55, first conductors 50, 52 and 54 form rectilinear strips, parallel to each other and regularly spaced. Of the conductors 50, 51, 52, 53, 54 and 55, second conductors 51, 53 and 55 also form straight, parallel and evenly spaced strips. The first conductors 50, 52 and 54, when viewed from above, are arranged perpendicular to the second conductors 51, 53 and 55. The conductors 50, 51, 52, 53, 54 and 55 are not directly connected to each other, however.

In FIG. 1, the first conductors 50, 52 and 54, on the one hand, and the second conductors 51, 53 and 55, on the other hand, are not coplanar, but are separated by a distance corresponding to a height, noted H, of a memory point 3. Each memory point 3 of the memory 1 is thus interposed between:
a first conductor, of the first conductors 50, 52 and 54; and
a second conductor, of the second conductors 51, 53 and 55.

In FIG. 1, each memory point 3, viewed from above, has a square shape, the length of one side of which measures P/2. This measurement P/2 is equivalent to half of a quantity called “pitch” P of the array formed by the conductors 50, 51, 52, 53, 54 and 55 of the memory 1. The memory points 3 in contact with the same conductor 50, 51, 52, 53, 54 or 55 are regularly spaced by a distance that is also equivalent to P/2 corresponding to half the pitch of the array. Still in FIG. 1, the conductors 50, 51, 52, 53, 54 and 55 have a rectangular shape where the short side is equal to half the pitch, P/2.

According to one embodiment, the memory 1 has a three-dimensional structure consisting of a stack of memory point layers separated by conductors. In the example shown in FIG. 1, memory points 3 are arranged under the second conductors 51, 53 and 55. These memory points 3 are contacted, at the bottom, by conductors (not shown), arranged orthogonally to the second conductors 51, 53 and 55 (like the first conductors 50, 52 and 54).

According to a preferred embodiment, each memory point 3 comprises a stack, defining an electrical connection in series:
of a resistive memory element 31;
of a layer 35 of electrically conductive material, e.g. metal layer 35; and
of a selector element 33, or selector 33.

In FIG. 1, the selector element 33 of a memory point 3 is in contact with the first conductor from among the first conductors 50, 52 and 54. The resistive memory element 31, in turn, is in contact with the second conductor from among the second conductors 51, 53 and 55. The metal layer 35 is interposed between the resistive memory element 31 and the selector element 33. Each memory point 3 of the memory 1, together with the first and second conductors contacting it, thus forms a structure stacked along the same axis, in which we distinguish:
a first structure consisting of the selector element 33, the first conductor 50, 52 or 54 and part of the metal layer 35; and
a second structure consisting of the resistive memory element 31, the second conductor 51, 53 or 55 and the other part of the metal layer 35.

The conductors 50, 51, 52, 53, 54 and 55 make it possible to address the memory points 3 of the memory 1. Each memory point 3 is in fact connected to a conductor pair of its own, consisting of a first and a second conductor.

To read or write in the resistive memory element 31 of a memory point 3 of the memory 1, the memory point 3 considered is first selected. The selection is made by applying a difference in potential between the two conductors forming the pair of conductors specific to the memory point 3 considered, for example. This difference in potential is of sufficient value to make it possible to modify a state of the selector element 33 so that an electric current can flow through the memory point 3 considered. This electric current makes it possible to read or write in the memory point 3, based on its intensity.

Once the read or write operation is completed, a difference in potential is no longer applied between the two conductors forming the conductor pair specific to the memory point 3 considered. This has the effect of returning the selector element 33 to an initial or resting state.

During a read or write operation in a memory point 3, a leakage current, noted Ileak, parasitizes with other memory points in contact with one of the two conductors of the pair specific to the memory point 3 considered. This leakage current Ileak is due to the fact that, in practice, the selector elements 33 at rest do not have infinite resistance.

In an oxide-based resistive memory (OxRAM) 1, the resistive memory element 31 preferably consists of hafnium dioxide (HfO2) and titanium (Ti). The hafnium dioxide (HfO2) and titanium (Ti) form a bilayer, for example. In the stacked structure previously described, the titanium layer forming the resistive memory element 31 is optionally located in contact with the metal layer 35 or the second conductor 51, 53 or 55 of the memory point 3.

The metal layer 35, interposed between the memory element 31 and the selector element 33, is made of titanium nitride (TiN), for example.

In a variant, the memory 1 is a conductive bridging random access memory (CBRAM).

The selector element 33 is an ovonic threshold switch (OTS). The selector element 33 is made from amorphous chalcogenide materials, for example. One property of amorphous chalcogenide materials is that when a voltage greater than a threshold voltage (Vth) is applied to them, they go from a highly resistive level to a highly conductive level. This highly conductive level has a lower electrical resistance than the highly resistive level. Conventionally, the highly resistive (or low conductive) level is said to correspond to a blocking state, preventing access to the memory element 31, while the highly conductive (or low resistive) level corresponds to an ‘on’ or conducting state, allowing access to the memory element 31.

The ‘on’ state is called volatile (or temporary, or non-permanent), because this ‘on’ state is maintained as long as an electric current flowing through the selector element 33 remains higher than a holding current, noted Ih. When the electric current flowing through the selector element 33 becomes lower than the holding current Ih, the selector element 33 is then in back the blocking state.

It is useful to take advantage of this property of amorphous chalcogenide materials to make selector elements 33 of the memory 1. The ‘on’ state makes it possible to have an electric current flow, in order to read or program in a memory element 31. The blocking state, which is highly resistive, prevents access to the memory element 31 and limits the leakage current Ileak in the non-selected or non-addressed memory points 3 of the memory 1.

FIG. 2 shows, schematically, one embodiment of an array 5 of memory points.

According to the embodiment of FIG. 2, the array 5 is a two-dimensional array of memory points. FIG. 2 corresponds to a top view of a layer of memory points 3 of the memory 1, for example (FIG. 1), between the first conductors 50, 52 and 54 on the one hand, and the second conductors 51, 53 and 55 on the other hand. All the memory points 3 of the array 5 are identical, except for the conductor pairs to which they are connected.

Each memory point 3 of the array 5 has a structure similar to that of the memory points 3 shown in relation to FIG. 1. Each memory point 3 thus comprises, in series:
the selector element 33, symbolized in FIG. 2 by a first rectangle;
the conductive metal layer 35, symbolized in FIG. 2 by a wire; and
the resistive memory element 31, symbolized in FIG. 2 by a second rectangle.

A specific memory point is considered in the example of FIG. 2, but everything described applies to all memory points of the array. In FIG. 2, the selector element 33 is connected to the conductor 52 on the one hand (point 523), and to the metal layer 35 on the other hand. The resistive memory element 31 is connected to the conductor 53 on the one hand (point 533) and to the metal layer 35 on the other hand.

Assuming that one wishes to read or write in the memory point 3 of the array 5, a voltage, noted V, is applied between the two conductors 52 and 53 connected on either side of the memory point 3. This voltage V is obtained by bringing the conductor 52 to an electric potential of value −V/2 and the conductor 53 to a higher electric potential, of value V/2, for example. All other conductors 50, 51, 54 and 55 are maintained at a potential of approximately zero volts (0 V). Thus, a difference in potential is imposed between the points 533 and 523, where the memory point 3 contacts the conductors 53 and 52 respectively, which is approximately equal to the voltage V.

When this voltage V reaches a value greater than or equal to the threshold voltage Vth of the selector element 33, this selector element 33 then becomes conductive and a current, noted I, flows (dotted arrows) in the memory point 3 and in part of the conductors 52 and 53 under the effect of the voltage applied to the memory point 3. The memory element 31 of the memory point 3 is then said to be selected by the selector element 33. The value of the current I is adapted, based on the desired read or write operation.

It is advisable to ensure that the selector element 33 has as low a leakage current Ileak as possible in the blocking state. This Ileak leakage current is detrimental to the operating performance of the array 5.

It is also desirable for the selector element 33 to be non-linear, i.e. to have the greatest possible difference in conductivity between the conducting state and the blocking state. This prevents neighboring memory points of a selected memory point (e.g. the memory points to the left and right of the memory point detailed in FIG. 2) from being activated unintentionally by leakage currents Ileak.

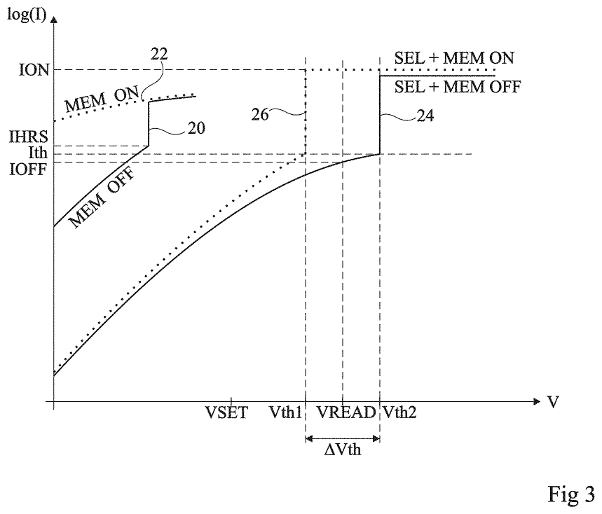

FIG. 3 shows a current/voltage characteristic of one embodiment of a memory point.

In FIG. 3, the x-axis corresponds to a voltage applied at the terminals of a memory element or memory point. The voltage V applied between the terminals of the memory element 31 alone relates to the curves 20 and 22 of the graph of FIG. 2, while the voltage V applied between the terminals 533 and 523 of the memory point 3 relates to the curves 24 and 26 of the graph of FIG. 2. The y-axis, in the logarithmic scale, corresponds to the current flowing through the resistive memory element 31 or the memory point 3, depending on the curve considered.

It is assumed that the resistive memory element 31 of the memory point 3 stores a binary value. Conventionally, a high state of this binary value is designated “ON” and a low state of this same binary value is designated “OFF”. In this example, the ON state is considered to correspond to a low-resistance state (LRS) and the OFF state is considered to correspond to a high-resistance state (HRS). The low-resistance state, ON, is of a lower electrical resistance than the high-resistance state, OFF.

The left side of FIG. 3 (curves 20 and 22) shows the behavior of the resistive memory element 31 alone. The right side of FIG. 3 (curves 24 and 26) illustrates the behavior of the memory point 3 (selector element 33, the conductive metal layer 35 and the resistive memory element 31 in series) in the high state, ON (curve 26), and the behavior of the memory point 3 in the low state, OFF (curve 24).

The resistive memory element 31 is changed over from the OFF state to the ON state by causing a current Ito flow through the memory point 3 at an intensity greater than a switching threshold, noted IHRS. In FIG. 3, the curve 20 (MEM OFF) is shown as a solid line and the curve 22 (MEM ON) as a dotted line. In order to avoid any untimely changeover in state during selection of the resistive memory element 31 of the memory point 3, it is ensured that the changeover threshold IHRS is greater than or equal to the threshold current Ith of the selector element 33.

For a read operation in the memory point 3, a voltage noted VREAD is applied between its terminals 533 and 523 (FIG. 2). In FIG. 3, this voltage VREAD is located within a voltage range, noted ΔVth, of between a threshold voltage, noted Vth1 (curve 26 in a dotted line, SEL+MEM ON) of the selector element 33 and another voltage, noted Vth2 (curve 24 in a solid line, SEL+MEM OFF).

The value of the current flowing in the memory point 3 is then measured. If the resistive memory element 31 is in the low state, OFF (curve 24), a current of value noted IOFF is measured by applying the voltage VREAD. On the other hand, if the resistive memory element 31 is in the high state, ON (curve 26), a current of value noted ION greater than the value IOFF is measured by applying the voltage VREAD. Measurement of the current flowing through the memory point 3, when a voltage VREAD within the range of voltages ΔVth is applied to its terminals, thus provides the binary value stored or recorded by the resistive memory element 31.

The resistive memory element 31 is initially in the ON state. The resistive memory element 31 is switched from the ON state to the OFF state by applying a reset voltage, noted VRESET (not shown in FIG. 3) to the memory point 3. The resistive memory 31 is then switched from this OFF state to the ON state by applying a programming voltage, noted VSET, lower than the reset voltage VRESET, at the memory point 3. To make the operation of the memory point 3 possible, it is ensured that the programming voltage VSET is less than or equal to the threshold voltage Vth of the selector element 33.

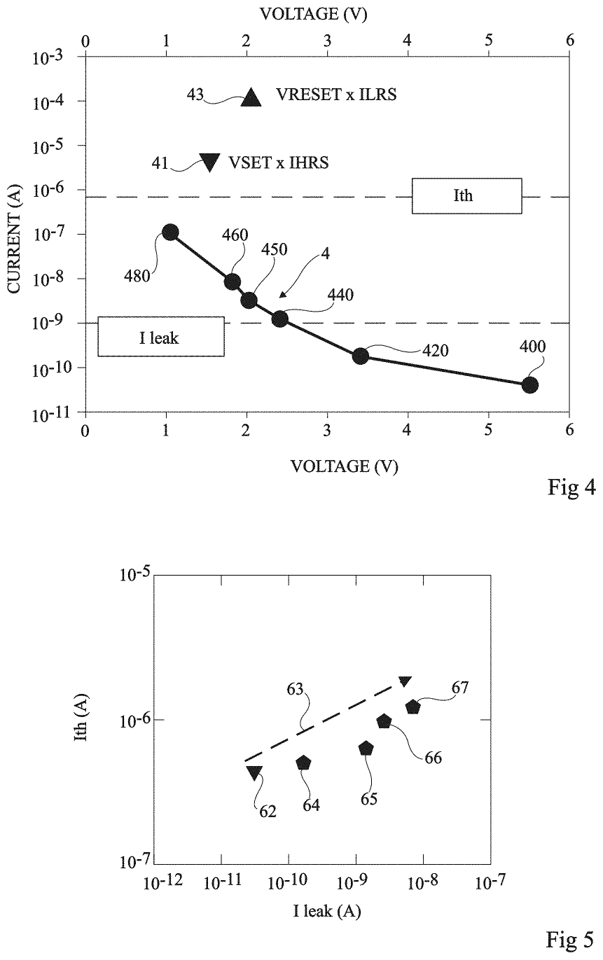

FIG. 4 shows a variation curve of characteristic quantities of an embodiment of a selector element.

In FIG. 4, the x-axis corresponds to a voltage, in volts, applied to the terminals of the selector element 33 (the curve 4) or of a memory element (the points 41, 43). The ordinate axis, in the logarithmic scale, corresponds to the current (in amperes) flowing through the selector element 33 (the curve 4) or the memory element (the points 41, 43).

The selector element 33 of the memory point 3 consists of a germanium (Ge), selenium (Se), arsenic (As) and tellurium (Te) based alloy. Again, according to this embodiment, the selector element 33 is an ovonic threshold switch. Alloys or compounds of germanium and selenium enriched in selenium, noted GS, have good thermal stability. This makes it possible to facilitate the implementation of manufacturing steps of memory points 3 of a memory such as the memory 1 (FIG. 1), with the GS material not very sensitive to temperatures below about 400° C.

However, the GS alloys used in the selector elements 33 are characterized by poor switching properties, in particular due to too high a threshold voltage Vth. The selector elements 33 based on GS alloys also exhibit poor switching endurance when successive transition cycles between their highly resistive level (blocking state) and their highly conductive level (conducting state), are applied to them.

According to the described embodiments, advantage is taken of the fact that the addition of materials called dopants improves the switching properties of selector elements made from GS alloys. In particular, adding an arsenic and tellurium-based material or compound, denoted AT, to a GS alloy of a selector element 33 makes it possible to reduce the threshold voltage Vth of the selector element 33 while improving its switching endurance. By adjusting the AT content (or AT proportion) in a GS alloy of which the selector element 33 is made, it is thus possible to obtain a balance between thermal stability of the alloy and switching properties of the selector element 33.

According to one preferred embodiment, the selector element 33 is manufactured from an alloy formed from a GS/AT pseudo-binary system, more preferably Ge₃Se₇As₂Te₃. The selector element 33 is manufactured by physical vapor deposition (PVD), for example. The Ge₃Se₇As₂Te₃ alloy thus consists of:
a first Ge₃Se₇ compound, corresponding here to the GS alloy, or composed of germanium and selenium; and
a second compound As₂Te₃, corresponding here to the AT alloy, or composed of arsenic and tellurium.

In FIG. 4, the curve 4 illustrates, for different AT alloy (As₂Te₃) contents in the GS/AT alloy of which the selector element 33 is made, a variation of the leakage current Ileak at the terminals of the selector element 33 (in amperes, on a logarithmic scale) based on its threshold voltage Vth (in volts). The leakage current Ileak of the selector element 33 is conventionally measured at a voltage equal to half the threshold voltage Vth. The AT alloy content is measured in atomic percent in this example. The alloy preferably has an arsenic and tellurium compound content of between about 20% and about 80%, preferably between 20% and 80%.

The curve 4 has six points, with each corresponding to a different AT alloy content in the GS-AT alloy:
a first point 400 corresponds to a zero AT content, i.e. a GS alloy consisting only of the GS alloy (Ge₃Se₇);
a second point 420 corresponds to an AT content equal to 20%, i.e. a GS-AT alloy consisting of 80% GS alloy and 20% AT alloy (As₂Te₃);
a third point 440 corresponds to an AT content equal to 40%, i.e. a GS-AT alloy consisting of 60% GS alloy and 40% AT alloy;
a fourth point 450 corresponds to an AT content of 50%, i.e. a GS-AT alloy consisting of 50% GS alloy and 50% AT alloy (a stoichiometric mixture of GS alloy and AT alloy);
a fifth point 460 corresponds to an AT content of 60%, i.e. a GS-AT alloy consisting of 40% GS alloy and 60% AT alloy; and
a sixth point 480 corresponds to an AT content of 80%, i.e. a GS-AT alloy consisting of 20% GS alloy and 80% AT alloy.

It is of interest to seek to adjust the threshold voltage Vth, the threshold current Ith and/or the leakage current Ileak of the selector element 33, in particular to associate this selector element 33 with a resistive memory element 31, to make them compatible. In this example, the programming voltage VSET of the resistive memory element 31 is assumed to be approximately equal to 1.5 V (point 41, VSET×IHRS). Again, in this example, the reset voltage VRESET of the resistive memory element 31 is assumed to be approximately equal to 2 V (point 43, VRESET×ILRS).

As discussed in connection with the preceding Figures, it is then sought to obtain a selector element 33 having a threshold voltage Vth greater than or equal to the programming voltage VSET of the resistive memory element 31. This makes it possible to ensure that the selector element 33 is compatible with the resistive memory element 31.

Additionally, it may also be sought to make the threshold current Ith of the selector element 33 less than or equal to the changeover threshold current IHRS of the resistive memory element 31. The closer the threshold current Ith of the selector element 33 is to the changeover threshold current IHRS of the resistive memory element 31, the larger the programming window. The ideal case would therefore be that Ith is equal to IHRS.

In addition, it may also be sought to ensure that the leakage current Ileak is as low as possible. The lower the Ileak leakage current, the larger the size of the envisaged memory array can be.

Thus, according to the example characteristics (41, 43) of the resistive memory element 31 shown in FIG. 4, this amounts to selecting a GS-AT alloy having an arsenic and tellurium compound (As₂Te₃) content equal to about 40%, preferably equal to 40% (point 440 in FIG. 4). This results in a selector element 33 characterized by:
a leakage current Ileak of about 1 nA, sufficiently low to guarantee non-linearity, making it possible to limit the leakage currents in an array 5 of 1 Mbits (in other words, a memory 1, consisting of an array 5 comprising one million memory points 3);
a threshold voltage Vth of about 2.4 V; and
a threshold current Ith of about 5 μA.

Thus, for any memory type (OxRAM, CBRAM, or PCM), the selector consisting of a GS-AT alloy has proportions of either of its constituent GS or AT compounds such that it has the following features, in order of priority, taken alone or in combination:
Vth (selector)>VSET (memory element 31);
Ith (selector)<IHRS (memory element 31); and/or
Ileak (selector) is the smallest possible leakage current, taking into account the two priority inequalities cited above.

If one wishes to manufacture a selector element 33 for a memory element 31 with known characteristics (VSET, IHRS), one can thus adjust the GS-AT alloy composition by means of the curve 4 in FIG. 4. This makes it possible to adapt the threshold voltage Vth and the leakage current Ileak based on the resistive memory element 31.

A memory 1 (FIG. 1) is thus manufactured according to a method comprising the following steps, for example:
manufacturing resistive memory elements 31; and
in connection with the resistive memory elements 31, manufacturing at least selector elements 33 consisting of a germanium, selenium, arsenic and tellurium based GS-AT alloy. This GS-AT alloy composition is then optimized based on the electrical properties of the resistive memory elements 31.

FIG. 5 shows another variation curve of characteristic quantities of one embodiment of a selector element 33.

In FIG. 5, the x-axis corresponds to the leakage current Ileak, in amperes, while the y-axis corresponds to the threshold current Ith, in amperes.

As discussed in connection with FIG. 4, the selector element 33 is assumed to be an ovonic threshold switch composed of a GS-AT alloy, preferably Ge₃Se₇As₂Te₃. The focus here is on the variation of the leakage current Ileak and the threshold current Ith based on the content composed of arsenic and tellurium, i.e. AT alloy in the selector element 33.

In the example shown in FIG. 5, the AT alloy content is varied in order to reach an operating area compatible with a resistive memory element 31. Starting from a zero AT alloy content (triangle 62), an increase in the AT alloy content (arrow 63) leads to a simultaneous increase in the values of the leakage current Ileak and the threshold current Ith for increasing AT alloy contents (pentagons 64 to 67, corresponding to AT alloy contents of 20%, 40%, 50% and 60%, respectively).

In order to make a selector element 33 that offers the largest possible programming window with the resistive memory element 31, a GS-AT alloy with an AT content is thus selected that makes it possible to obtain a threshold current value Ith that is as close as possible to the changeover threshold current IHRS of the memory element 31, while limiting the leakage currents Ileak, depending on the desired array size. Specifically, this FIG. 5 illustrates that the threshold current Ith and the leakage current Ileak of the selector 33 can vary based on the amount of the AT or GS compound present in the GS-AT alloy.

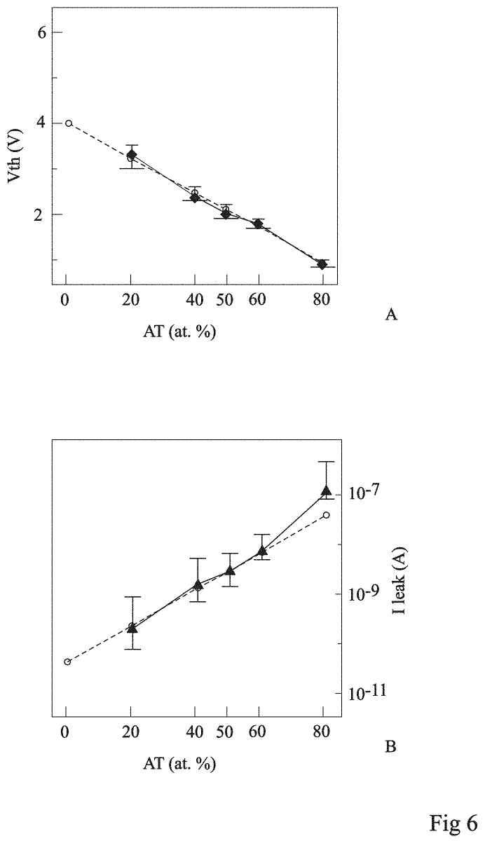

FIG. 6 shows other variation curves of characteristic quantities of one embodiment of a selector element 33, by views A and B.

As discussed in connection with FIGS. 4 and 5, the selector element 33 is assumed to be an ovonic threshold switch composed of a GS-AT alloy, preferably Ge₃Se₇As₂Te₃.

In view A, the variation of the threshold voltage Vth of the selector element 33 (y-axis, in volts) based on its AT alloy content or proportion (x-axis, in atomic percent) in the GS-AT mixture is of interest. It can be seen that the threshold voltage Vth decreases as the AT alloy content (in As₂Te₃, in this example) increases. Noting the As₂Te₃ content or concentration as CAT and a thickness of the selector element 33 as tOTS, advantage is taken of the fact that the value of the threshold voltage Vth of the selector element 33 is linked to the atomic percentage of the arsenic and tellurium compound in the GS-AT alloy, in particular in Ge₃Se₇As₂Te₃, by a relationship of the type:

Vth=(−1.5×10⁻³×CAT+0.13)×tOTS+(−4×10⁻⁴×CAT+0.7) [Math 1]

In view B, the variation of the leakage current Ileak of the selector element 33 (y-axis, in amperes) based on its AT alloy content (x-axis, in atomic percent) in the GS-AT alloy, namely in Ge₃Se₇As₂Te₃, is of interest. It can be seen that the Ileak leakage current increases as the AT alloy content (in As₂Te₃, in this example) increases. Still noting the As₂Te₃ content or concentration as CAT and a thickness of the selector element 33 as tOTS, and noting the exponential function as exp, advantage is taken of the fact that the value of the leakage current Ileak is linked to the atomic percentage of the arsenic and tellurium compound in the GS-AT alloy, in particular in Ge₃Se₇As₂Te₃, by a relationship of the type:

Ileak=exp(0.09×CAT)×exp((75.8/tOTS)−27) [Math 2]

Various embodiments and variants have been described. Those skilled in the art will understand that certain features of these embodiments can be combined and other variants will readily occur to those skilled in the art. In particular, the content CAT composed of arsenic and tellurium in the GS-AT alloy of the selector element 33, may be adjusted according to other characteristic properties of the resistive memory element 31.

Finally, the practical implementation of the embodiments and variants described herein is within the capabilities of those skilled in the art based on the functional description provided hereinabove.

1. A selector for a memory cell, intended to change from a resistive state to a conductive state so as to respectively prohibit or authorize access to the memory cell, characterized in that it is made of a GS-AT alloy consisting of germanium, selenium, arsenic and tellurium.

2. The selector according to claim 1, wherein said GS-AT alloy is Ge₃Se₇As₂Te₃.

3. The selector according to claim 1, wherein said GS-AT alloy has an arsenic and tellurium AT compound content of between 20% and 80%.

4. The selector according to claim 1, wherein said GS-AT alloy has an arsenic and tellurium AT compound content of 40%.

5. The selector according to claim 1, wherein said GS-AT alloy is obtained by physical vapor deposition.

6. The selector according to claim 1, wherein it is an ovonic threshold switch.

7. A memory point comprising:
a resistive memory element; and
a selector according to claim 1.

8. The memory point according to claim 7, wherein the proportions of arsenic, tellurium, germanium and selenium are such that a threshold voltage of said selector is greater than or equal to a programming voltage of said resistive memory element.

9. The memory point according to claim 7, wherein the content of the compound AT of arsenic and tellurium and the content of the compound GS of germanium and selenium are such that a threshold voltage of said selector is greater than or equal to a programming voltage of said resistive memory element.

10. The memory point according to claim 7, wherein the content of the compound AT of arsenic and tellurium and the content of the compound GS of germanium and selenium are such that a threshold current of said selector is less than or equal to a state switching current of said resistive memory element.

11. A memory having a plurality of memory points according to claim 7.

12. The memory according to claim 11, consisting of a resistive oxide memory or a conductive link random access memory.

13. The memory according to claim 11, wherein each memory point comprises, in series:
said selector;
said resistive memory element; and
an electrically conductive layer interposed between said selector and said resistive memory element.

14. A method for manufacturing a memory comprising the following steps:
manufacturing at least one resistive memory element; and
in connection with said resistive memory element, manufacturing at least one selector made of a GS-AT alloy consisting of germanium, selenium, arsenic and tellurium.
